(19) United States
(12) Patent Application Publication
(10) Pub. No.: US 2024/0175138 A1
(43) Pub. Date: May 30, 2024

(54) SYSTEMS AND METHODS FOR CONTROLLING PRESSURE IN SUBSTRATE PROCESSING SYSTEMS

(71) Applicant: ASM IP HOlding B.V., Almere (NL)

(72) Inventors: Fan Gao, Chandler, AZ (US); Peipei Gao, Chandler, AZ (US); Xing Lin, Chandler, AZ (US); Arun Murali, Tempe, AZ (US); Gregory Deye, Seattle, WA (US); Frederick Aryeetey, Phoenix, AZ (US); Amir Kajbafvala, Chandler, AZ (US); Caleb Miskin, Mesa, AZ (US); Alexandros Demos, Scottsdale, AZ (US)

(21) Appl. No.: 18/518,393

(22) Filed: Nov. 22, 2023

Related U.S. Application Data
(60) Provisional application No. 63/428,600, filed on Nov. 29, 2022.

(51) Int. Cl. C23C 16/52; C23C 16/44; C23C 16/46; H01L 21/67

(52) U.S. Cl. CPC C23C 16/52; C23C 16/4412; C23C 16/46; H01L 21/67017; H01L 21/67126; H01L 21/67253

(57) ABSTRACT

Systems and methods controlling the pressure differential between two sealed chambers connected by a gate valve in preparation for a gate valve opening event. Such systems and methods may adjust gas pressure in at least one of the chambers, if needed, until the pressure differential between the two chambers is at a predetermined pressure differential level. In some more specific examples, one chamber may constitute a substrate handling chamber, the other chamber may constitute a reaction chamber (e.g., for depositing one or more layers on a surface of a substrate), and the gate valve opening event may allow a substrate to be transferred from one chamber to the other (e.g., from the reaction chamber into the substrate handling chamber).

### CROSS-REFERENCE TO RELATED APPLICATION(S)

This application claims the benefit of U.S. Provisional Application 63/428,600 filed on Nov. 29, 2022, the entire contents of which are incorporated herein by reference.

### FIELD OF INVENTION

This invention relates to systems and methods for processing substrates and moving substrates between two or more connected chambers. Some aspects of this technology relate to systems and methods for calibrating pressure sensors included in substrate processing systems. Additional aspects of this technology relate to systems and methods for controlling pressures in two sealed chambers in preparation for a gate valve opening event in which a pathway will be opened between two chambers.

### BACKGROUND OF THE DISCLOSURE

During substrate processing, such as semiconductor wafer manufacturing, thin layers of material are deposited on a substrate to build up a multilayer product. Such processing requires highly controlled and highly sanitary processing conditions to precisely deposit the desired layer materials and avoid contamination. Any source of contamination can lead to degraded product quality.

### SUMMARY OF THE DISCLOSURE

This summary is provided to introduce a selection of concepts relating to this technology in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Some aspects of this technology relate to systems and methods for controlling the pressure differential between two sealed chambers connected by a gate valve in preparation for a gate valve opening event. Such systems and methods adjust gas pressure in at least one of the chambers until the pressure differential between the two chambers is at a predetermined pressure differential level (e.g., 0.75 torr or less). In some more specific examples, one chamber may constitute a substrate handling chamber, the other chamber may constitute a reaction chamber (e.g., for depositing one or more layers on a surface of a substrate), and the gate valve opening event may allow a substrate to be transferred from one chamber to the other (e.g., from the reaction chamber into the substrate handling chamber).

In some examples of this technology, such systems and methods may be used to reduce interfacial oxygen deposited on a substrate surface during substrate transfer (e.g., when moving a substrate between a substrate handling chamber and a reaction chamber) or other gate valve opening event.

Some additional or alternative aspects of this technology relate to substrate processing systems and methods in which a substrate is transferred between a substrate handling chamber and a reaction chamber through a gate valve. In such systems and methods, gas pressures in the two chambers are controlled in preparation for a gate valve opening event as follows:
(i) with the gate valve between the substrate handling chamber and the reaction chamber in a closed configuration thereby sealing the substrate handling chamber from the reaction chamber, fixing a reaction chamber pressure control valve at a first position, thereby holding the reaction chamber at a reaction chamber pressure;
(ii) measuring the reaction chamber pressure using a reaction chamber pressure sensor;
(iii) measuring a substrate handling chamber pressure in the substrate handling chamber using a substrate handling chamber pressure sensor; and
(iv) with the reaction chamber pressure control valve fixed at the first position, adjusting pressure in the substrate handling chamber using a substrate handling chamber pressure control valve to a pressure within a gate valve opening pressure range.

The gate valve opening pressure range comprises a pressure greater than or equal to the reaction chamber pressure but no more than the reaction chamber pressure plus a first predetermined amount (no more than a predetermined pressure differential).

Additionally or alternatively, some aspects of this technology relate to systems and methods for controlling pressure for a gate valve opening event in a substrate processing system that includes a substrate handling chamber that transfers substrates into and out of a reaction chamber through a gate valve. Such systems and methods include setting a reaction chamber pressure control valve for the reaction chamber fixed at a first position, thereby holding the reaction chamber at a reaction chamber pressure. Then, the methods include:
(a) receiving input indicating the reaction chamber pressure;
(b) receiving input indicating substrate handling chamber pressure;
(c) determining whether the reaction chamber pressure and the substrate handling chamber pressure are within a gate valve opening pressure range, wherein the reaction chamber pressure and the substrate handling chamber pressure are within the gate valve opening pressure range when the substrate handling chamber pressure is greater than or equal to the reaction chamber pressure but no more than the reaction chamber pressure plus a first predetermined amount; and
(d) while the reaction chamber pressure control valve remains at the fixed first position, if necessary, controlling a substrate handling chamber pressure control valve to adjust the substrate handling chamber pressure until the reaction chamber pressure and the substrate handling chamber pressure are within the gate valve opening pressure range.

Still additionally or alternatively, some aspects of this technology relate to substrate processing systems that include: (a) a reaction chamber; (b) a reaction chamber pressure sensor configured to measure reaction chamber pressure; (c) a reaction chamber pressure control valve; (d) a substrate handling chamber; (e) a substrate handling chamber pressure sensor configured to measure substrate handling chamber pressure; (f) a substrate handling chamber pressure control valve, wherein the substrate handling pressure control valve is electronically controllable; and (g) a gate valve between the reaction chamber and the substrate handling chamber, the gate valve switchable between an open configuration in which the reaction chamber and the substrate handling chamber are open to one another and a closed configuration in which the substrate handling chamber and the reaction chamber are sealed off from one another. An input system is configured to receive: (i) input data from the reaction chamber pressure sensor indicating the reaction chamber pressure, and (ii) input data from the substrate handling chamber pressure sensor indicating the substrate handling chamber pressure. Further, a control system is configured to send signals to adjust the substrate handling chamber pressure control valve in response to the input data from the reaction chamber pressure sensor and the input data from the substrate handling chamber pressure sensor and place the substrate handling chamber pressure within a gate valve opening pressure range. The substrate handling chamber pressure is within the gate valve opening pressure range when the substrate handling chamber pressure is greater than or equal to the reaction chamber pressure but no more than the reaction chamber pressure plus a first predetermined amount.

Alternatively, in the systems described above, (i) the substrate handling pressure chamber's pressure control valve may be fixed thereby holding the substrate handling chamber at its pressure set point and (ii) the control system may be configured to send signals to adjust the reaction chamber pressure control valve in response to the input data from the reaction chamber pressure sensor and the input data from the substrate handling chamber pressure sensor. The control system further may be configured to place the reaction chamber pressure at a level such that the substrate handling chamber pressure is greater than or equal to the reaction chamber pressure but no more than the reaction chamber pressure plus a first predetermined amount.

Still additional or other alternative aspects of this technology relate to calibration methods for calibrating the pressure sensors in the substrate handling chamber and the reaction chamber, e.g., in which the pressure readings made by the pressure sensor in one chamber (e.g., the substrate handling chamber pressure sensor) is used as a reference when calibrating the pressure sensor in the other chamber (e.g., the reaction chamber pressure sensor).

Still additional or other alternative aspects of this technology relate to systems and methods for placing two chambers within a predetermined gate valve opening pressure range and/or for determining whether two chambers are within the predetermined gate valve opening pressure range. One example of such systems and methods includes use of a balance valve gas line between the substrate handling chamber and the reaction chamber (e.g., connected between the gas exhaust lines of these two chambers). With the gate valve closed, the balance valve gas line can be opened to allow gas transfer between the two chambers (e.g., to at least start to equalize the pressure in the two chambers). Gas flow through the balance valve gas line can be used to determine if and when the chamber pressures are the same or substantially the same, e.g., to confirm when the predetermined gate valve opening pressure range has been reach and a gate valve opening event can begin.

Still additional or other alternative aspects of this technology relate to systems and methods for determining whether two chambers are within a predetermined gate valve opening pressure range using a differential pressure manometer. A gas line from one chamber (e.g., from the substrate handling chamber) is connected to a reference port of the differential pressure manometer, and a gas line from the other chamber (e.g., the reaction chamber) is connected to the measuring port of the differential pressure manometer. Output from the differential pressure manometer provides information regarding the pressure difference between the two chambers and allows a determination of whether and when the chamber pressures are within the desired gate valve opening pressure range.

Additional aspects, configurations, embodiments, and examples are described in more detail below.

### BRIEF DESCRIPTION OF THE DRAWING FIGURES

The present disclosure is illustrated by way of example and not limited in the accompanying figures in which like reference numerals indicate similar elements and in which:

FIG. 1 illustrates at least a portion of a multi-chambered substrate processing system in which aspects of the present technology may be incorporated and/or used;

FIG. 2 provides a more detailed view of features of a reaction chamber for substrate processing that may be used in accordance with at least some aspects of this technology;

FIG. 3A is a perspective view of a multilayered product and FIG. 3B is a graph showing potential features of such a product produced under some processing conditions;

FIG. 4 illustrates gate valve opening processes under different pressure differential conditions during a gate valve opening event;

FIGS. 5A-5H illustrate systems and methods for measuring and controlling chamber pressures according to some aspects of this technology;

FIGS. 6A and 6B illustrate systems and methods for measuring and controlling chamber pressures according to additional or alternative aspects of this technology;

FIGS. 7A-7F illustrate systems and methods for measuring and controlling chamber pressures according to additional or alternative aspects of this technology using a balance valve gas line; and

FIGS. 8A and 8B illustrate systems and methods for measuring and controlling chamber pressures according to additional or alternative aspects of this technology using a differential pressure manometer.

Where the same reference number appears in multiple drawings, that reference number is used to refer to the same or similar parts or components in all of the views and at all of the locations where that reference number appears.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride, and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber (also called a “reaction chamber” herein) where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

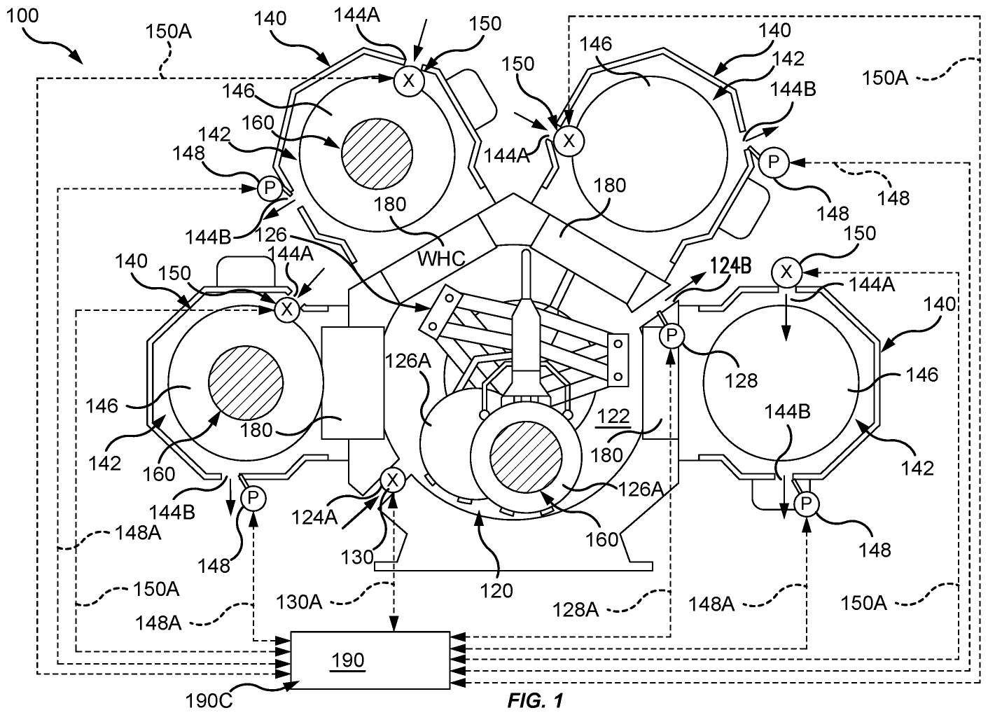

FIG. 1 depicts a substrate processing system 100 in accordance with some examples of this technology and/or in which aspects of this technology may be practiced. This example substrate processing system 100 includes a substrate handling chamber 120 connected to a plurality of reaction chambers 140. The substrate handling chamber 120 includes an interior chamber 122 that can be sealed to a gas tight condition and maintained at a desired pressure. A gas inlet 124A and a gas exhaust 124B are provided with the substrate handling chamber 120 so that the gas composition within its interior chamber 122 can be controlled. A substrate handling chamber 120 pressure sensor 128 (e.g., at or near the gas exhaust 124B line) measures pressure within the interior chamber 122, and a substrate handling chamber pressure control valve 130 (“PCV”) may be used to change and control pressure within the interior chamber 122. The pressure control valve 130 may comprise an electronically controllable pressure control valve, e.g., in one of the gas inlet 124A line or the gas exhaust 124B line. The interior chamber 122 includes a transfer system 126 (e.g., one or more computer controllable robotic arms) used to move substrates 160 on one or more transfer platforms 126A, e.g., in manners to be described in more detail below.

As noted above, the substrate handling chamber 120 is connected to a plurality of reaction chambers 140. While four reaction chambers 140 are shown in the example of FIG. 1, a substrate handling chamber 120 could be connected (or connectable) to any number of reaction chambers 140 (e.g., one or more). Further, while FIG. 1 shows each reaction chamber 140 having substantially the same size and structure, a single substrate handling chamber 120 could be connected to reaction chambers 140 having different structures, different sizes, and/or different uses (e.g., with individual reaction chambers 140 configured to perform different functions with respect to substrates 160 included therein). Also, in some examples of this technology, a single reaction chamber 140 may hold two or more substrates 160 simultaneously during a processing step.

In this illustrated substrate processing system 100 of FIG. 1, each of the reaction chambers 140 includes an interior chamber 142 that can be sealed to a gas tight condition and maintained at a desired pressure. Each reaction chamber 140 further includes a gas inlet 144A and a gas exhaust 144B so that the gas composition within its interior chamber 142 can be controlled. A reaction chamber pressure sensor 148 (e.g., at or near the gas exhaust 144B line) measures pressure within the interior chamber 142, and a reaction chamber pressure control valve 150 may be used to change and control pressure within the interior chamber 142. The pressure control valve 150 may comprise an electronically controllable pressure control valve, e.g., in one of the gas inlet 144A line or the gas exhaust 144B line. The interior chambers 142 include a substrate support 146 used to hold the substrates 160 during a processing step (e.g., during a layer deposition process, during an etching process, etc.).

The substrate handling chamber 120 is connected to each of the reaction chambers 140 by a respective gate valve 180. When closed, the gate valves 180 sealingly separate the substrate handling chamber 120 from the respective reaction chambers 140. In the gate valve 180 closed condition, the interior chamber 122 of the substrate handling chamber 120 may be maintained at a different pressure (and contain a different gas composition) than the interior chamber 142 of the reaction chamber 140. In the gate valve 180 open condition, a physical pathway is opened between the interior chamber 122 of the substrate handling chamber 120 and the interior chamber 142 of the reaction chamber 140. Thus, in the gate valve 180 open condition, a portion of the transfer system 126 including a transfer platform 126A can extend through the gate valve 180 and into a reaction chamber 140's interior chamber 142, e.g., to enable a substrate 160 to be placed on a substrate support 146, removed from a substrate support 146, and/or transferred between the substrate handling chamber 120 and a reaction chamber 140.

This illustrated substrate processing system 100 further includes a control system 190C, which may include one or more computer systems 190. Such computer system(s) 190 may have a conventional structure (e.g., a PC, laptop, desktop computer, etc.), including one or more input ports, e.g., including input ports for receiving input data from substrate handling chamber pressure sensor 128, reaction chamber pressure sensors 148, substrate handling chamber pressure control valve 130, reaction chamber pressure control valves 150, and/or gate valves 180. Such input ports may include USB ports, plug receptacles (e.g., configured to engage a wired input cord connected to pressure sensors 128, 148, pressure control valves 130, 150, and/or gate valves 180), wireless input ports (e.g., configured to receive wireless transmissions from pressure sensors 128, 148, pressure control valves 130, 150, and/or gate valves 180), and the like, including conventional input ports and components known and used in the computer control arts. The computer system(s) 190 further may include one or more computer processors (e.g., conventional microprocessors) that receive input data (e.g., from pressure sensors 128 and/or 148 and/or from pressure control valves 130 and/or 150 and/or from gate valves 180), perform functions defined by a computer algorithm on data, and generate output data based on the input and algorithm(s), etc. In addition, the control system 190C (e.g., computer system(s) 190) further may include one or more output systems (e.g., including output ports for transmitting output data from the computing system 190 to control one or more of the substrate handling chamber pressure sensor 128, reaction chamber pressure sensors 148, substrate handling chamber pressure control valve 130, reaction chamber pressure control valves 150, and/or gate valves 180). The output system may use the same physical structures and port hardware as used for the input ports (thereby comprising “input/output ports”) and may communicate with (e.g., send control instructions to) the pressure sensors 128, 148, pressure control valves 130, 150, and/or gate valves 180 in a wired and/or wireless manner using the same physical hardware as used to send input from the pressure sensors 128, 148, pressure control valves 130, 150, and/or gate valves 180 to the computer system(s) 190.

As shown schematically in FIG. 1, each of the pressure sensors 128, 148 is connected to the control system 190C. These pressure sensors 128, 148 may be configured to: (i) send data to the computer system 190 (e.g., input data representing pressure measured within its respective interior chamber 122, 142, etc.) and (ii) receive data from the computer system 190 (e.g., data enabling pressure sensor 128, 148 calibration activities, etc.). Also, as shown schematically in FIG. 1, each of the pressure control valves 130, 150 is connected to the control system 190C. These pressure control valves 130, 150 may be configured to: (i) send data to the computer system 190 (e.g., input data representing its current setting position, etc.) and (ii) receive data from the computer system 190 (e.g., data changing a pressure control valve 130, 150 position or setting, data changing gas flow rates to enable gas pressure changes within its respective interior chamber 122, 142, data fixing or locking a pressure control valve 130, 150 in a fixed position, etc.). Thus, line 128A in FIG. 1 represents an electronic communication link (wired or wireless) between the pressure sensor 128 and the control system 190C, e.g., for reading, controlling, and communicating with and/or other computer control of the substrate handling chamber pressure sensor 128. Line 130A represents an electronic communication link (wired or wireless) between the pressure control valve 130 of the substrate handling chamber 120 and the control system 190C, e.g., for reading, controlling, and communicating with and/or other computer control of the substrate handling chamber 120's pressure control valve 130. Similarly, lines 148A in FIG. 1 represent an electronic communication link (wired or wireless) between the pressure sensors 148 and the control system 190C, e.g., for reading, controlling, and communicating with and/or other computer control of the reaction chambers pressure sensors 148. Lines 150A represent an electronic communication link (wired or wireless) between the pressure control valves 150 and the control system 190C, e.g., for reading, controlling, and communicating with and/or other computer control of the reaction chambers 140's pressure control valves 150. Control system 190C may be configured to communicate with and control each reaction chamber 140's pressure sensor 148 and/or pressure control valve 150 independent of any other pressure sensors 148 and/or pressure control valves 150 present in the overall substrate processing system 100.

Also, while not shown in FIG. 1, control system 190C and its computer system(s) 190 also may be operatively coupled to the gate valve(s) 180 by electronic communication links, e.g., to enable a gate valve opening action (e.g., unlocking a gate valve 180, opening a gate valve 180, etc.) or to disable a gate valve opening action (e.g., to lock a gate valve 180 or maintain a gate valve 180 in a locked position). In at least some aspects of this technology, control system 190C and its computer system(s) 190 will be used to measure and control gas pressure within the interior chambers 122 and/or 142 for a gate valve 180 opening event and/or a substrate 160 transfer event, as will be described in more detail below.

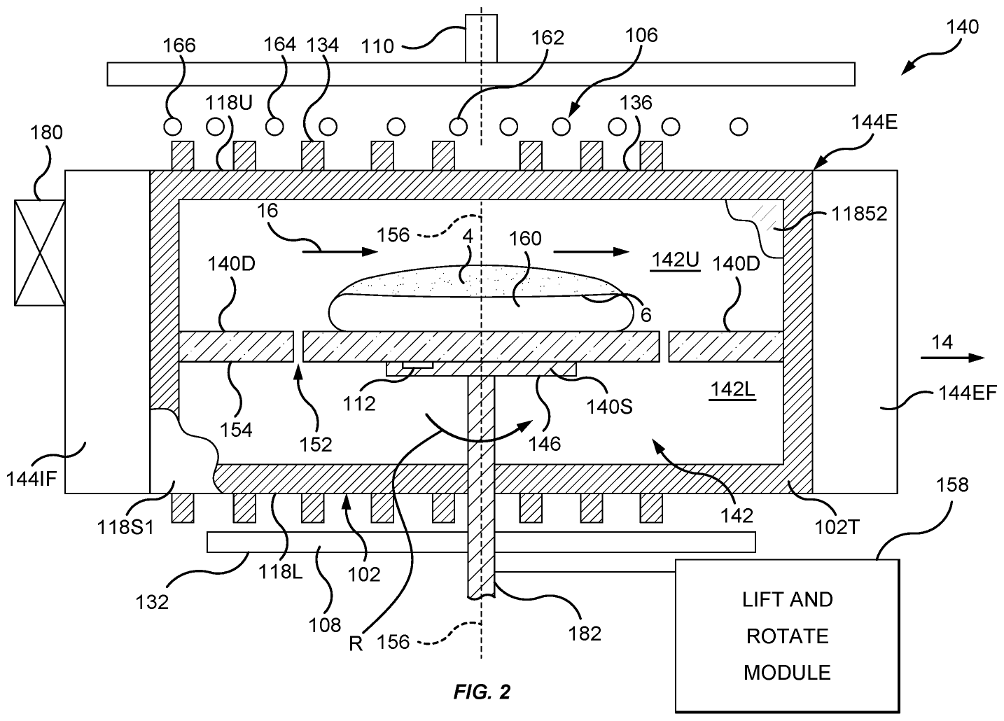

FIG. 2 provides a view of one example reaction chamber 140 arrangement in accordance with aspects of this technology (although the features shown in FIG. 2 could be provided in any one or more of the reaction chambers 140 shown in FIG. 1). The reaction chamber 140 arrangement includes a chamber body 102 and a substrate support 146. The reaction chamber 140 arrangement also includes an upper heater element array 106 and a lower heater element array 108. The reaction chamber 140 arrangement further includes a pyrometer 110, a thermocouple 112, a controller, and a wired or wireless link (e.g., schematically represented by lines 148A and 150A and the control system 190C shown in FIG. 1). Although a specific arrangement is shown and described herein it is to be understood and appreciated that the reaction chamber 140 arrangement may include other elements and/or omit elements shown and described herein and remain within the scope of the present disclosure.

The chamber body 102 is configured to flow a precursor 16 across the substrate 160 and has an upper wall 118U, a lower wall 118L, a first sidewall 118S1, and a second sidewall 118S2. The upper wall 118U extends longitudinally between an injection end 144I and a longitudinally opposite exhaust end 144E of the chamber body 102, is supported horizontally relative to gravity, and is formed from a transmissive material 102T. The lower wall 118L is below and parallel relative to the upper wall 118U of the chamber body 102, is spaced apart from the upper wall 118U by an interior chamber 142 of the chamber body 102, and is also formed from the transmissive material 102T. The first sidewall 118S1 longitudinally spans the injection end 144I and the exhaust end 144E of the chamber body 102, extends vertically between the upper wall 118U and the lower wall 118L of the chamber body 102, and is formed from the transmissive material 102T. The second sidewall 118S2 is parallel to the first sidewall 118S1, is laterally opposite and spaced apart from the first sidewall 118S1 by the interior chamber 142 of the chamber body 102, and is further formed from the transmissive material 102T. In certain examples, the transmissive material 102T may include a ceramic material such as sapphire or quartz. In accordance with certain examples, the chamber body 102 may include a plurality of external ribs 134. The plurality of external ribs 134 may extend laterally about an exterior 136 of the chamber body 102 and be longitudinally spaced between the injection end 144I and the exhaust end 144E of the chamber body 102. In certain examples, the one or more of the walls 118U, 118L, 118S1, 118S2 may be substantially planar. In accordance with certain examples, one or more of the walls 118U, 118L, 118S1, 118S2 may be arcuate or dome-like in shape. It is also contemplated that, in accordance with certain examples, the chamber body 102 may include no ribs.

An injection flange 144IF and an exhaust flange 144EF may be connected to the injection end 144I and the exhaust end 144E, respectively, of the chamber body 102. The injection flange 144IF may fluidly couple a precursor delivery arrangement to the interior chamber 142 of the chamber body 102 and be configured to provide the precursor 16 to the interior chamber 142 of the chamber body 102. The exhaust flange 144EF may fluidly couple the interior chamber 142 of the chamber body 102 to an exhaust arrangement 14. The exhaust flange 144EF may be configured to communicate the residual precursor and/or reaction products issued by the reaction chamber 140 arrangement during deposition of a material layer onto the substrate 160. In this respect, the chamber body 102 may have a cold wall, cross-flow reactor configuration.

A divider 140D, a support member 140S, and a shaft member 182 may be arranged within the interior chamber 142 of the chamber body 102. The divider 140D may be fixed within the interior chamber 142 of the chamber body 102 and divide the interior chamber 142 of the chamber body 102 into an upper chamber 142U and a lower chamber 142L. The divider 140D may further define an aperture 152 therethrough, the aperture 152 fluidly coupling the upper chamber 142U of the chamber body 102 to the lower chamber 142L of the chamber body 102. The divider 140D may be formed from an opaque material 154. The opaque material 154 may include silicon carbide.

The substrate support 146 may be configured to seat thereon the substrate 160 and supported at least partially within the aperture 152 for rotation R about a rotation axis 156. The substrate support 146 may seat the substrate 160 such that a radially-outer peripheral of the substrate 160 abuts the substrate support 146 while a radially-inner central portion of the substrate 160 is spaced apart from the substrate support 146. The support member 140S may be arranged below the substrate support 146 and along the rotation axis 156. The support member 140S may be further arranged within the lower chamber 142L of the chamber body 102, and fixed in rotation relative to the substrate support 146 about the rotation axis 156 for rotation with the substrate support 146. The substrate support 146 may be formed from an opaque material, such as the opaque material 154 or a graphite material. The support member 140S may be formed from a transmissive material, such as the transmissive material 102T.

The shaft member 182 may be arranged along the rotation axis 156 and fixed in rotation relative to the support member 140S about the rotation axis 156. The shaft member 182 may also extend through the lower chamber 142L of the chamber body 102 and through lower wall 118L of chamber body 102. The shaft member 182 may further operably connect a lift and rotate module 158 to the substrate support 146, the lift and rotate module 158 in turn configured to rotate R the substrate support 146 and the substrate 160 about the rotation axis 156 during deposition of the material layer onto an upper surface 6 of the substrate 160. The lift and rotate module 158 may further cooperate with a gate valve 180 and a lift pin arrangement to seat and unseat the substrate 160 from the substrate support 146, such as through a substrate handling robot arranged within a cluster-type platform in selective communication with the interior chamber 142 of the chamber body 102 through the gate valve 180. See FIG. 1. In certain examples the shaft member 182 may be formed from a transmissive material, such as the transmissive material 102T.

The upper heater element array 106 is configured to heat the substrate 160 and/or the material layer 4 during deposition onto the substrate 160 by radiantly communicating heat into the upper chamber 142U of the chamber body 102. In this respect the upper heater element array 106 may include a first upper heater element 162, a second upper heater element 164, and at least one third upper heater element 166. The first upper heater element 162 may include a linear filament and a quartz tube enclosing the linear filament and/or may include one or more bulb or lamp-type heater elements. The first upper heater element 162 may be supported above the upper wall 118U of the chamber body 102, extend laterally between the first sidewall 118S1 and the second sidewall 118S2 of the chamber body 102, and may further overlay the substrate support 146. The second upper heater element 164 and the at least one third upper heater element 166 may be similar to the first upper heater element 162, may additionally be longitudinally spaced apart from the first upper heater element 162, and may further be longitudinally spaced apart from the rotation axis 156. The second upper heater element 164 may further overlay (e.g., intersect) a peripheral edge of the substrate 160. The at least one third upper heater element 166 may overlay the divider 140D. In certain examples, the upper heater element array 106 may include eleven (11) or twelve (12) upper heater elements. Each upper heater element of the upper heater element array 106 may be longitudinally spaced apart from one another above the upper wall 118U of the chamber body 102 between the injection end 144I and the exhaust end 144E of the chamber body 102.

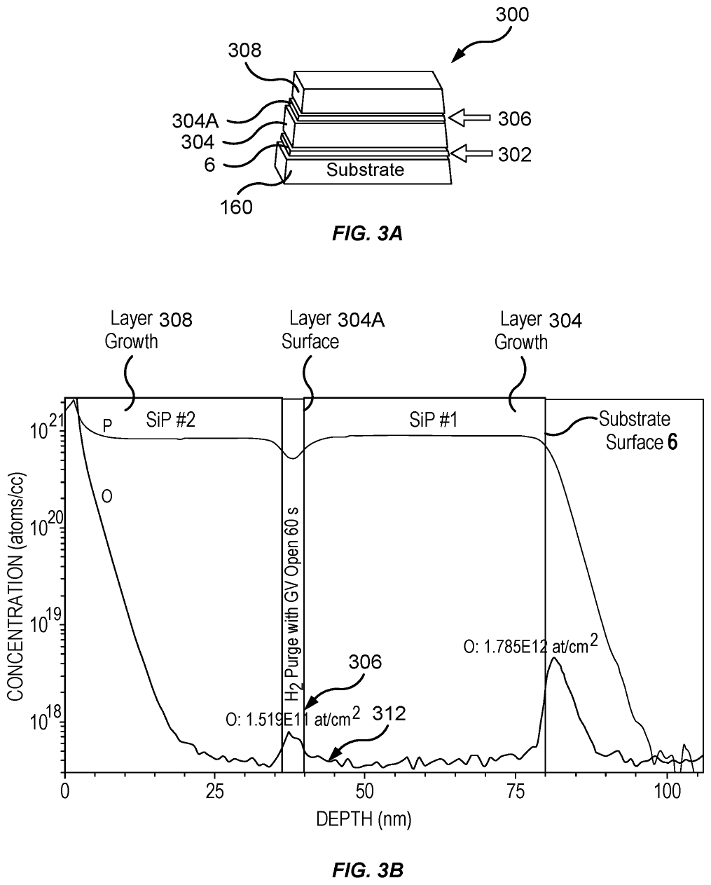

Using equipment of the types described above in conjunction with FIGS. 1 and 2, substrates 160 (e.g., wafers) can be processed (e.g., during semiconductor manufacturing) to deposit layers of material onto the surface 6 of the substrate 160. Such processes can be used, for example, for epitaxial growth on a substrate. FIG. 3A illustrates an example substrate 160 onto which layers 304 and 308 are deposited to form a multilayer product 300. The process starts with a cleaned substrate, although one or more surfaces (including surface 6 on which the layer 304 is to be deposited) may include native oxide material and/or may accumulate oxide material 302 after its initial cleaning and before the deposition process begins. The accumulated oxide material 302 may be deposited, e.g., from the atmosphere in which the substrate 160 is stored while awaiting processing (e.g., from moisture or contaminants in atmospheric gas where with substrate 160 is stored after initial cleaning).

Referring also to FIGS. 1 and 2, at a desired processing time, the cleaned substrate 160 may be moved into a substrate handling chamber 120 (e.g., immediately after initial cleaning). In the illustrated example, the substrate 160 may be placed onto transfer platform 126A of transfer system 126. Then, with an appropriate gate valve 180 open, the transfer system 126 (e.g., robotic arm) may move the substrate 160 on the transfer platform 126A, through the gate valve 180, into a desired reaction chamber 140, and onto the reaction chamber 140's substrate support 146. The transfer platform 126A may be retracted through the gate valve 180, and the gate valve 180 may be closed to sealingly separate the substrate handling chamber 120 (and its interior chamber 122) from the reaction chamber 140 (and its interior chamber 142). In this sealed and gate valve 180 closed configuration, a desired gas may be moved through the reaction chamber 140 (from the injection end 144I to the exhaust end 144E) to deposit a desired material layer 304 (e.g., an SiP layer) on the substrate 160 surface 6.

After a first material layer 304 is deposited on the substrate 160, the processing protocol may require the gate valve 180 to be opened to allow access to the partially completed layered product. For example, the substrate 160 (and deposited layer 304) may need to be moved from one reaction chamber 140 to another, may need to be repositioned within the reaction chamber 140's interior chamber 142, and/or may require some other attention before the next processing step (e.g., another material layer depositing step, an etching step, etc.) can be performed. After such an intermediate handling step is completed, with the substrate 160 in a new or the same reaction chamber 140, the relevant gate valve 180 can be closed, and gas for forming the next layer 308 can be introduced into the reaction chamber 140 (via a precursor gas injected into interior chamber 142) and deposited on the first layer 304.

FIG. 3B graphically illustrates the concentration of oxygen atoms on a multilayer product 300 of the type shown in FIG. 3A based on depth into the multilayer product 300. The right side of the graph (beginning at about 80 nm) illustrates layer 304 deposited on the substrate 106's surface 6. The central area of the graph (between 36-40 nm) corresponds to the depth at the time when the gate valve 180 was opened (after layer 304 was deposited but before layer 308 was deposited). The left side of the graph (from 0 nm to 36 nm) illustrates layer 308 deposited on layer 304's surface. As shown, even when using a hydrogen gas (H₂) purge for a 60 second gate valve 180 opening event, an increased oxygen content developed between layers 304 and 308 (see area 306 in FIG. 3A). Such increased oxygen content (also called “interfacial oxygen”) can lead to degraded EPI crystal quality.

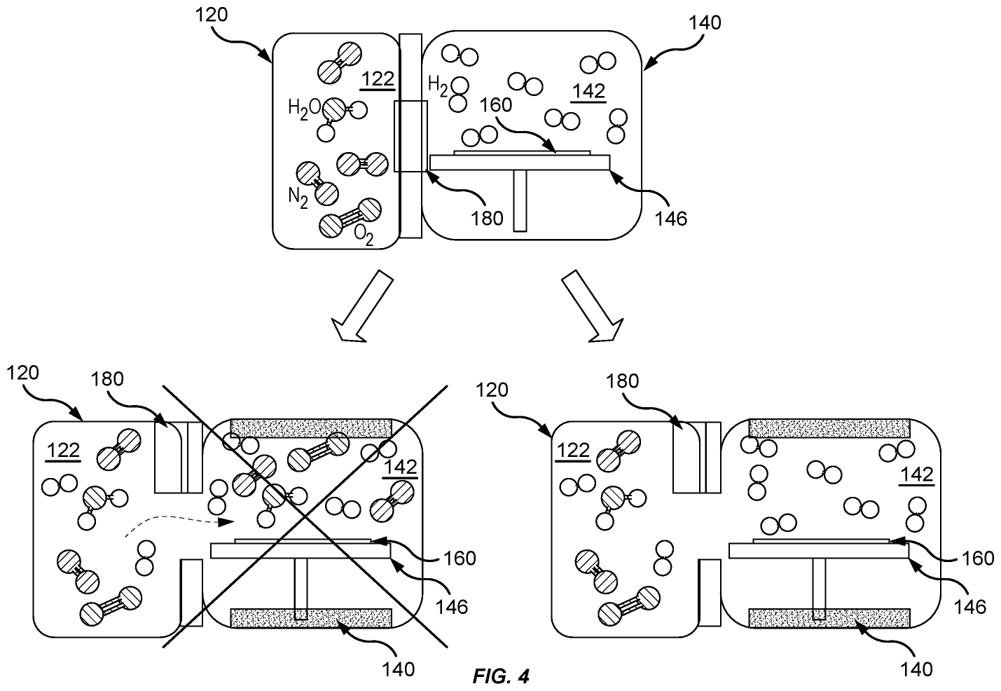

FIG. 4 further illustrates these process steps under different gate valve 180 opening conditions. The top of FIG. 4 shows the substrate handling chamber 120 and reaction chamber 140 in a separated and sealed condition, e.g., with the gate valve 180 closed and while substrate 160 processing takes place in interior chamber 142. Thus, the substrate handling chamber 120 atmosphere (e.g., including water, oxygen, and nitrogen in this example) remains sealed off from the reaction chamber 140 and its atmosphere (e.g., including hydrogen gas from the gas purge in this example). If gas pressure in the substrate handling chamber 120 is significantly higher than in the reaction chamber 140 when the gate valve 180 is opened (e.g., during an intermediate handling step as described above), gas can transfer between the substrate handling chamber 120 and the reaction chamber 140, e.g., as shown at the bottom left side of FIG. 4. In this situation, opening the gate valve 180 between the layer 304 and layer 308 depositing steps can lead to interfacial oxygen and/or other undesired material 306 (e.g., contaminants from the interior chamber 122 of the substrate handling chamber 120) depositing on the surface 304A of the exposed and previously formed layer 304 before layer 308 is deposited. The oxygen adsorption rate has been found to be nearly three times faster when gas from a substrate handling chamber 120 is introduced into a reaction chamber 140, e.g., during a gate valve 180 opening event. This adsorbed oxygen, if too high, can lead to degraded epitaxial crystal quality.

On the other hand, in accordance with aspects of this technology and as shown at the bottom right side of FIG. 4, if gas pressures in the substrate handling chamber 120 and the reaction chamber 140 are substantially the same (e.g., within a “gate valve opening pressure range” described below) when the gate valve 180 is opened (e.g., during an intermediate handling step as described above), substantially less gas is interchanged between the substrate handling chamber 120 and the reaction chamber 140. Thus, controlling the substrate handling chamber 120 pressure and the reaction chamber 140 pressure to be within a desired “gate valve opening pressure range” can result in less interchange of gases between the substrate handling chamber 120 and the reaction chamber 140 and less contamination.

A “gate valve opening pressure range,” as that term is used herein, means that the two pressures on opposite sides of the sealed gate valve 180 are within a “predetermined range” or “ΔP” of one another (e.g., before the gate valve 180 is opened). In some examples of this technology, this “predetermined range” or “ΔP” will be 0.75 torr or less, and in some examples, 0.6 torr or less, 0.5 torr or less, 0.3 torr or less, or even 0.2 torr or less. In some examples, the desired ΔP may be 0 torr or as closed to 0 torr as possible.

In some specific examples of this technology, the substrate handling chamber 120 and the reaction chamber 140 will be within the “gate valve opening pressure range” when (a) the substrate handling chamber 120 is at a pressure (PSHC) greater than or equal to the reaction chamber 140 pressure (PRC), but (b) no more than the reaction chamber 140 pressure (PRC) plus a predetermined amount (PRC+ΔP). Specifically, when:

PRC≤PSHC≤PRC+ΔP.

If the substrate handling chamber pressure (PSHC) is too high during a gate valve 180 opening event, this may cause gas from the substrate handling chamber 120 to enter the reaction chamber 140 while the gate valve 180 is open, as shown at the bottom left of FIG. 4. If the substrate handling chamber 120 pressure (PSHC) is below the reaction chamber 140 pressure (PRC) while the gate valve 180 is open, this may cause gas from the reaction chamber 140 to move into the substrate handling chamber 120, which could then be (undesirably) introduced as a contaminant into one or more of the other reaction chambers 140 connected with the substrate handling chamber 120 when their respective gate valves 180 are opened.

Thus, at least some aspects of this technology relate to (a) systems and methods for determining whether two chambers connected by a gate valve (e.g., a substrate handling chamber 120 connected with a reaction chamber 140 by a gate valve 180) are at pressures suitable for a gate valve 180 opening event and/or (b) systems and methods for preparing two such chambers for a gate valve 180 opening event. With a substrate 160 in one of the chambers (substrate handling chamber 120 or reaction chamber 140) and the gate valve 180 in a closed configuration, at least some aspects of this technology relate to systems and methods that adjust gas pressure in at least one of the substrate handling chamber 120 or the reaction chamber 140 until the substrate handling chamber 120 pressure (PSHC) and the reaction chamber 140 pressure (PRC) are within a gate valve pressure opening range as described above. Once within the gate valve pressure opening range, the gate valve 180 may be opened, and further actions can be taken (e.g., the substrate 160 can be transferred between the substrate handling chamber 120 and the reaction chamber 140 via the gate valve 180 and/or other actions can be taken). Opening gate valve 180 when the substrate handling chamber 120 pressure (PSHC) and the reaction chamber 140 pressure (PRC) are within the gate valve pressure opening range as described above can help reduce interfacial oxygen deposited on a substrate and/or reduce other contamination during the gate valve 180 opening event, e.g., thereby improving multilayer product 300 quality.

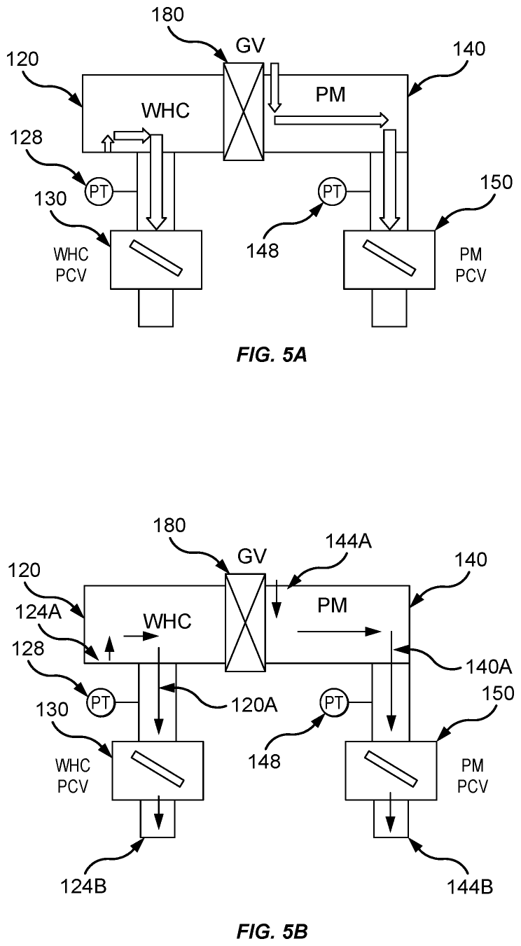

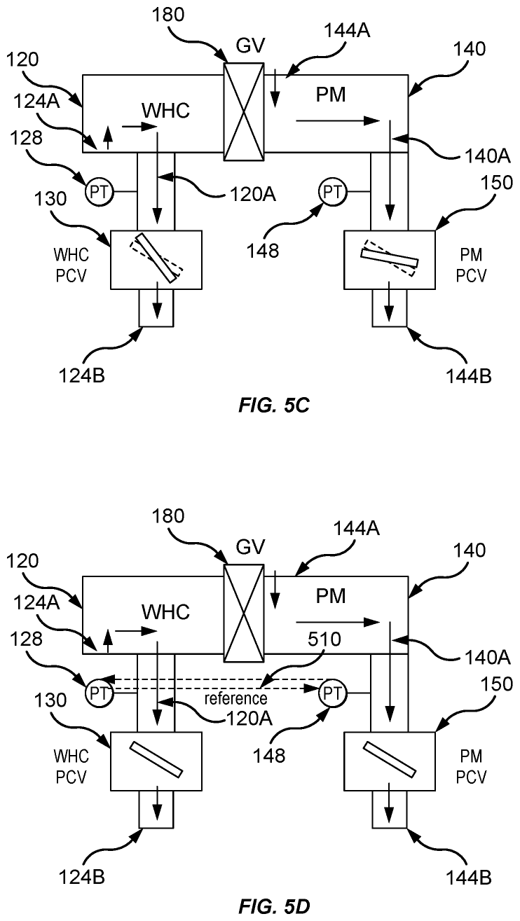

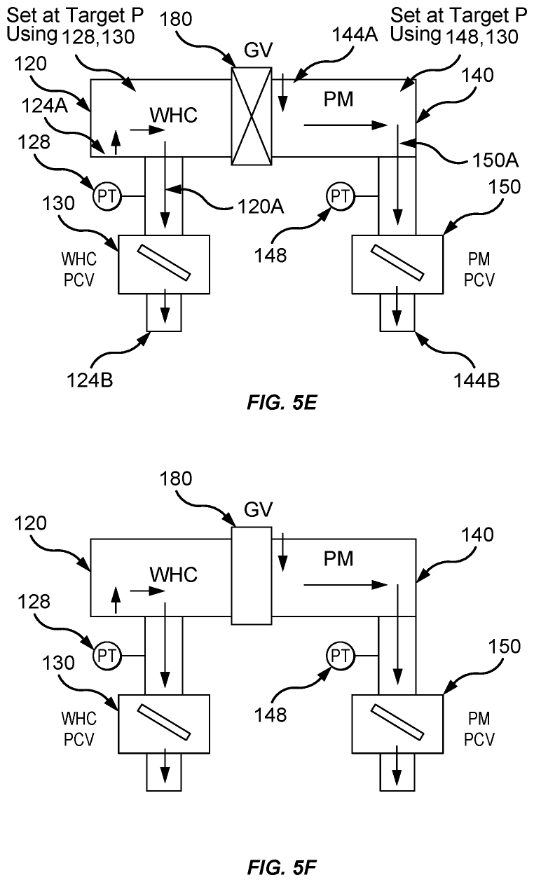

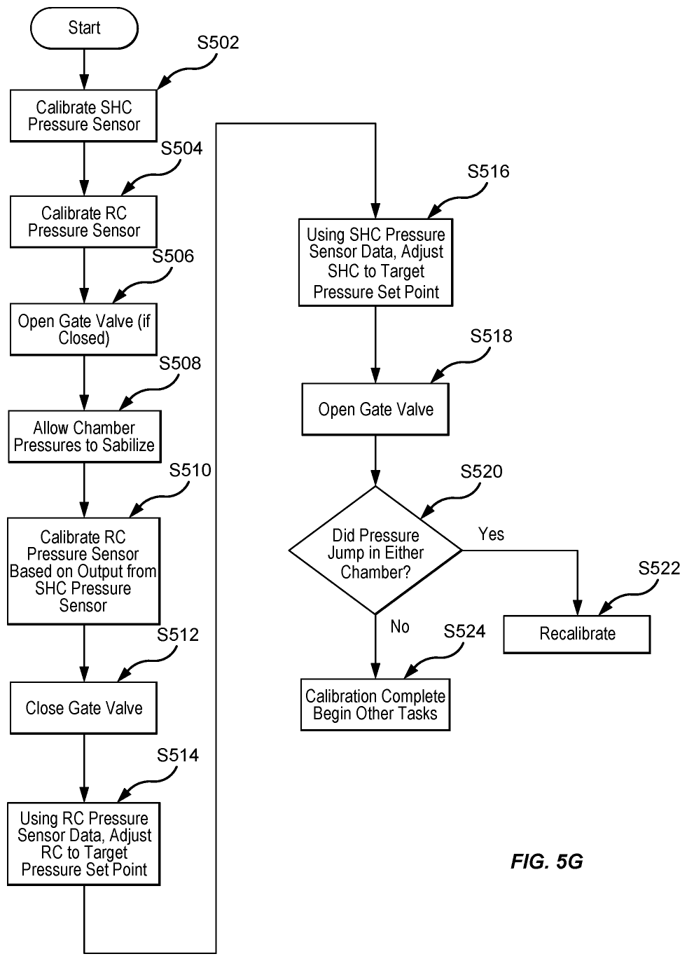

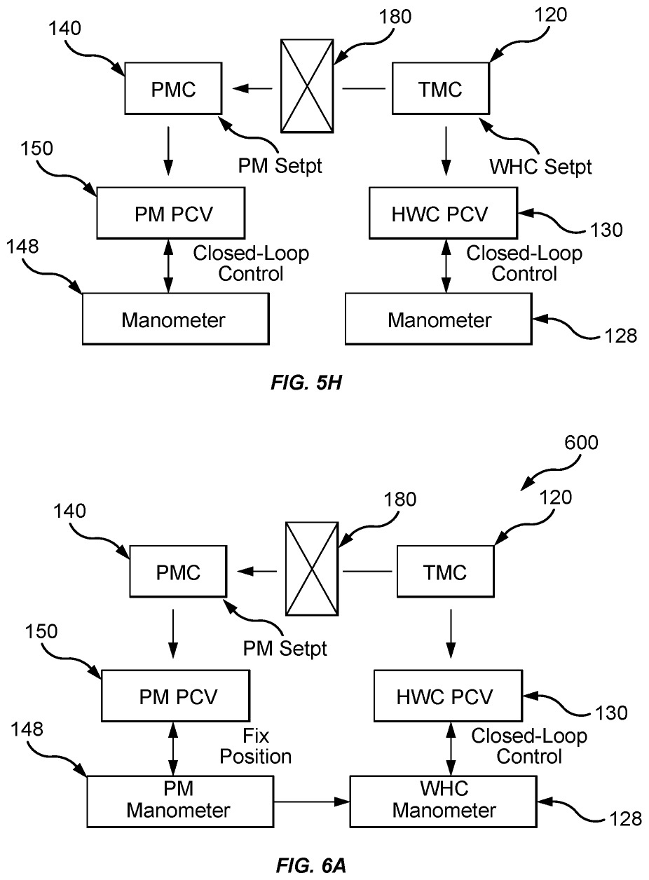

Some more specific examples of systems and methods for determining whether pressures are suitable and/or for controlling pressures in two chambers for a gate valve opening event are described in more detail below in conjunction with FIGS. 5A-8B.

FIGS. 5A-5G provide examples of systems and methods for preparing two chambers connected by a gate valve (e.g., a substrate handling chamber 120 and a reaction chamber 140 connected by gate valve 180) for a gate valve opening event by assuring that the pressures in the two chambers are within a desired and predetermined “gate valve opening pressure range.” Because the pressure differential ΔP for a gate valve opening pressure range in at least some examples of this technology may be quite small (e.g., with a “ΔP” of 0.75 torr or less, and in some examples, 0.6 torr or less, 0.5 torr or less, 0.3 torr or less, or even 0.2 torr or less (e.g., as close to 0 torr as possible)), the substrate handling chamber 120's pressure sensor 128 readings and the reaction chamber 140's pressure sensor 148 readings should be accurately comparable with one another. But such sensors do not always completely agree. For example, due to calibration differences, drift, sensor surface contamination, or the like, two sensors exposed to identical pressures may display somewhat different pressure readings (e.g., one sensor may read 10 torr while another sensor in the exact same environment may read the same pressure as 11 torr). Thus, in accordance with at least some examples of this technology, the reaction chamber 140's pressure sensor 148 will be calibrated using output from the substrate handling chamber 120's pressure sensor 128, so that the pressure readings from the two pressure sensors 128, 148 will be based on the same standard.

While not required for every gate valve 180 opening event, the first step of this example process comprises individual calibration steps for the substrate handling chamber 120's pressure sensor 128 and the reaction chamber 140's pressure sensor 148. As shown in FIG. 5A and as step S502 in FIG. 5G, with the gate valve 180 closed, the substrate handling chamber 120's pressure sensor 128 is calibrated, e.g., using the pressure sensor manufacturer's suggested calibration procedure (e.g., with the substrate handling chamber 120 pumped down to a base calibration pressure for the substrate handling chamber 120 (e.g., at or near an anticipated pressure during typical use)). Similarly, also with the gate valve 180 closed, the reaction chamber 140's pressure sensor 148 is calibrated at step S504, e.g., using that pressure sensor manufacturer's suggested calibration procedure (e.g., with the reaction chamber 140 pumped down to a base calibration pressure for the reaction chamber 140 (e.g., at or near an anticipated pressure during typical use)). Thus, as a starting point, the two pressure sensors 128 and 148 are individually calibrated in manners consistent with their typical uses and under conditions of their typical use.

Then, with the gate valve 180 closed, gas flow and pressure in the substrate handling chamber 120 and the reaction chamber 140 are adjusted, if necessary, to typical pressure ranges present during use, e.g., prior to a gate valve 180 opening event (e.g., at pressures typically present during a substrate 160 transfer process). See gas flow arrows 120A and 140A and the transfer status conditions shown in FIG. 5B. These steps place the substrate handling chamber 120 and the reaction chamber 140 in condition for further calibration steps described below.

As the next step in this calibration process, as shown in FIG. 5C, the gate valve 180 is opened (Step S506, FIG. 5G), and the pressures in the substrate handling chamber 120 and the reaction chamber 140 are allowed to stabilize (Step S508) with the gate valve 180 open. The open gate valve 180 should allow the pressures in the substrate handling chamber 120 and the reaction chamber 140, once stabilized, to equal one another. Then, as the next step, as shown in FIG. 5D and at Step S510 in FIG. 5G, output 510 from the substrate handling chamber 120's pressure sensor 128 is used as a reference to further calibrate the reaction chamber 140's pressure sensor 148. More specifically, because pressure in the substrate handling chamber 120 and the reaction chamber 140 should be equal at this time, this calibration step S510 assures that the pressure reading by the reaction chamber pressure sensor 148 exactly matches the pressure reading from the substrate handling chamber 120's pressure sensor 128. The output of the reaction chamber 140's pressure sensor 148 can be adjusted (or calibrated) during this step S510, if needed, to exactly match output of the substrate handling chamber 120's pressure sensor 128 (e.g., so that each sensor's output reads 10.0 torr). Adjustment and calibration of the pressure sensor 148 based on output from the substrate handling chamber pressure sensor 128 may be performed manually or under computer control (e.g., using computer system 190). Alternatively, if desired, output from the reaction chamber 140's pressure sensor 148 could be used as the reference to further calibrate the substrate handling chamber 120's pressure sensor 128. In that instance, adjustment and calibration of the pressure sensor 128 based on output from the reaction chamber pressure sensor 148 may be performed manually or under computer control (e.g., using computer system 190).

In these manners, the pressure sensors 128 and 148 in both the substrate handling chamber 120 and the reaction chamber 140 are calibrated at the exact same pressures and their outputs are synchronized based on readings taken from one of the pressure sensors (e.g., pressure sensor 128). The use of the output from pressure sensor 128 to calibrate pressure sensor 148 when both are exposed to the same pressures (with the gate valve 180 open and the substrate handling chamber 120 and reaction chamber 140 open to one another) helps assure that the pressure readings from the two pressure sensors 128 and 148 are validly comparable at a later time, when the gate valve 180 is closed and the substrate handling chamber 120 and the reaction chamber 140 are sealed and isolated from one another.

In at least some examples of this technology, this calibration technique further may include a calibration check procedure. As part of this check procedure, at Step S512 (FIG. 5G), the gate valve 180 is closed. Then, using the reaction chamber 140's pressure sensor 148, pressure in the reaction chamber 140 is adjusted (e.g., using pressure control valve 150) to a target pressure set point (e.g., within a range typically used during substrate 160 processing). See Step S514. Independently, with the gate valve 180 closed, using the substrate handling chamber 120's pressure sensor 128, pressure in the substrate handling chamber 120 is adjusted (e.g., using pressure control valve 130) to the same target pressure set point (e.g., within a range typically used during substrate 160 processing). See Step S516 and FIG. 5E. Once each of the substrate handling chamber 120 and the reaction chamber 140 is independently set at the target pressure set point and the independent pressures and gas flows have time to stabilize, the gate valve 180 is opened (Step S518 and FIG. 5F). As the gate valve 180 is opened, each pressure sensor 128, 148 is monitored (manually or electronically) to determine if a pressure jump occurs when the gate valve 180 is opened. See Step S520. If the pressure sensor 128, 148 in either the substrate handling chamber 120 or the reaction chamber 140 displays a significant pressure change when the gate valve 180 opens, it can be concluded that the pressures in the substrate handling chamber 120 and the reaction chamber 140 were not substantially the same, and recalibration may be needed at Step S522 (e.g., returning to Step S502, S504, or S506). If neither pressure sensor 128, 148 displays a significant pressure change when the gate valve 180 opens, it can be concluded that the pressures in the substrate handling chamber 120 and the reaction chamber 140 were substantially the same, and the calibration process is complete (Step S524). The overall substrate processing system 100 then may be ready to perform other tasks, including a gate valve 180 opening event and/or other substrate processing tasks (e.g., layer deposition, etc.).

Once calibrated, e.g., using the methods described above in conjunction with FIGS. 5A-5G, systems and methods in accordance with at least some examples of this technology may operate in the manner shown in FIG. 5H. In such systems and methods, pressure in the substrate handling chamber 120 is measured by substrate handling chamber 120's pressure sensor 128 and the pressure can be adjusted and controlled within the substrate handling chamber 120 using pressure control valve 130. In some examples, pressure control valve 130 may be manipulated to control pressure in substrate handling chamber 120 based on output from the pressure sensor 128 to place and maintain the pressure at a substrate handling chamber 120 set point, optionally under computer control. Similarly, pressure in the reaction chamber 140 is measured by reaction chamber 140's pressure sensor 148 and the pressure can be adjusted and controlled in the reaction chamber 140 using pressure control valve 150. In some examples, pressure control valve 150 may be manipulated to control pressure in reaction chamber 140 based on output from the pressure sensor 148 to place and maintain the pressure at a reaction chamber 140 set point, optionally under computer control. Because of the prior calibration method(s) (described in conjunction with FIGS. 5A-5G), the pressures in the substrate handling chamber 120 and the reaction chamber 140 may be considered to be within the gate valve 180 opening pressure range when the separate readings from the two pressure sensors 128, 148 show the pressures to be within the ΔP pressure range. When within the gate valve opening pressure range in the system and method of FIG. 5H, the gate valve 180 can be opened (or the system and/or method may enable the gate valve 180 to be opened (e.g., placing the gate valve 180 in an unlocked condition using a computer controlled locking mechanism)). Alternatively, systems and methods according to this aspect of the present technology may simply inform an operator that the system is in condition for the gate valve 180 to be safely opened.

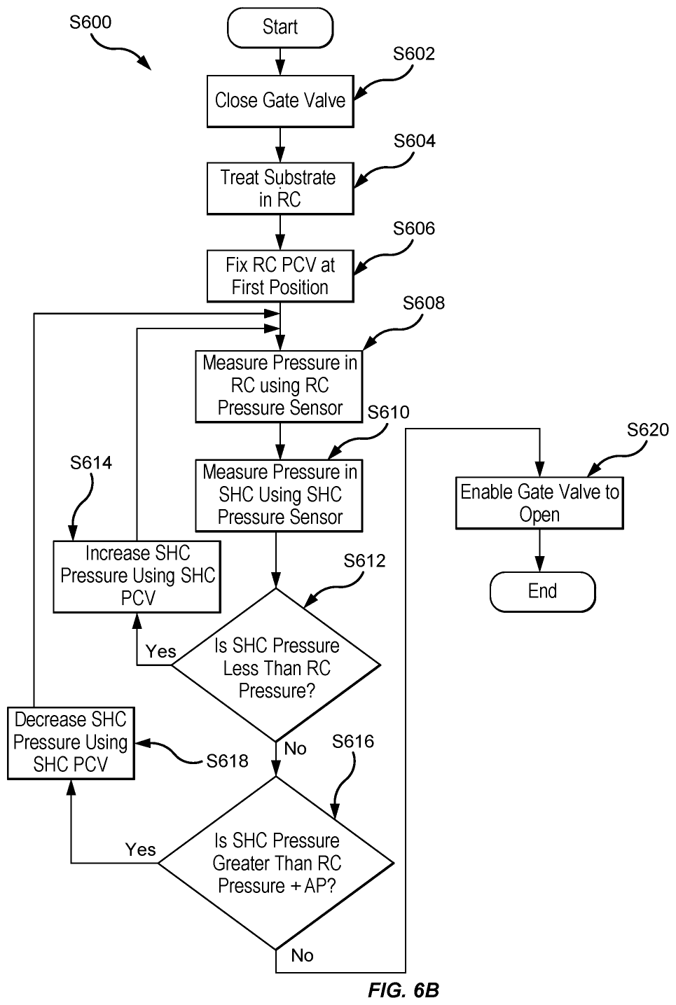

Systems and methods in accordance with other aspects of this technology, however, may take additional steps to assure that the pressures in the substrate handling chamber 120 and the reaction chamber 140 are within the gate valve opening pressure range prior to opening gate valve 180 (or enabling it to be opened). FIGS. 6A and 6B illustrate an example of such systems 600 and methods S600.

Similar to other systems described above, FIG. 6A illustrates a substrate processing system 600 including a substrate handling chamber 120, e.g., that transfers substrates 160 into and out of one or more reaction chambers 140 through a gate valve 180. The substrate handling chamber 120 includes a pressure sensor 128 and a pressure control valve 130, e.g., for controlling pressure within the substrate handling chamber 120. Also, the reaction chamber 140 includes a pressure sensor 148 and a pressure control valve 150, e.g., for controlling pressure within the reaction chamber 140. Further, the pressure sensor 148 for the reaction chamber 140 may have been calibrated using output from the pressure sensor 128 for the substrate handling chamber 120 as a reference during calibration, e.g., in the manners described above in conjunction with FIGS. 5A-5G. A method of controlling pressure in the substrate handling chamber 120 and the reaction chamber 140 for a gate valve 180 opening event in this system 600 is described below.

In such methods S600, the process begins with the gate valve 180 in a closed configuration (Step S602). At this time, the substrate 160 may be in either of the reaction chamber 140 (e.g., being treated in a layer depositing process, an etching process, etc., Step S604) or the substrate handling chamber 120 (e.g., awaiting introduction into a reaction chamber 140). Eventually the processing protocol will reach a time when a gate valve 180 opening event must occur, e.g., to move a substrate 160 between the substrate handling chamber 120 and the reaction chamber 140, in either direction. To initiate this gate valve 180 opening event, the gate valve 180 first is maintained in its closed configuration thereby maintaining the seal between the substrate handling chamber 120 and the reaction chamber 140. Then, the reaction chamber 140's pressure control valve 150 is fixed at a first position (Step S606) to thereby hold the reaction chamber 140 at its present reaction chamber pressure set point. In some examples of systems and methods according to this aspect of this technology, a computer controlled pressure control valve 150 may be locked in place or disabled under computer control in order to assume the fixed position and to maintain a constant pressure in the reaction chamber 140. In other examples of this technology, the pressure control valve 150 may be manually locked and/or operators may simply be instructed to maintain the pressure control valve 150 in a fixed position. The remaining steps in the method S600 take place with the gate valve 180 maintained in its closed configuration and the reaction chamber 140's pressure control valve 150 fixed at the first position.

At Step S608, pressure in the reaction chamber 140 is measured using the reaction chamber 140's pressure sensor 148 and at Step S610, pressure in the substrate handling chamber 120 is measured using its pressure sensor 128. Steps S608 and S610 may take place in any order and/or simultaneously. Next, these pressure readings are compared to determine if the pressures are within a gate valve 180 opening pressure range. While other algorithms are possible, in this illustrated method, first the system and method determine if the substrate handling chamber 120 pressure is less than the reaction chamber 140 pressure (Step S612). If “yes,” the substrate handling chamber 120's pressure control valve 130 is manipulated (e.g., manually or under computer control) to increase gas pressure in the substrate handling chamber 120 (Step S614). The process then returns to Step S608 (or Step S610).

If the substrate handling chamber 120's pressure is not less than the reaction chamber 140's pressure at Step S612 (answer “no”), the system and method then determine if the substrate handling chamber 120 pressure is greater than the reaction chamber 140 pressure plus a predetermined pressure differential amount “ΔP” (Step S616). As discussed above, in at least some examples of this technology, this “ΔP” may be 0.75 torr or less, and in some examples, 0.6 torr or less, 0.5 torr or less, 0.3 torr or less, or even 0.2 torr or less (in some examples, as close to 0 torr as possible).

If “yes,” i.e., if the substrate handling chamber 120 pressure (PSHC) is greater than the reaction chamber 140 pressure (PRC) plus a predetermined pressure differential amount “ΔP” (answer “yes” at Step S616), the substrate handling chamber 120's pressure control valve 130 is manipulated (e.g., manually or under computer control) to decrease gas pressure in the substrate handling chamber 120 (Step S618). The process then returns to Step S608 (or Step S610).

If the substrate handling chamber 120 pressure (PSHC) is not greater than the reaction chamber 140 pressure (PRC) plus a predetermined pressure differential amount “ΔP” (answer “no” at Step S616), the system and method then determine that the substrate handling chambers 120 and the reaction chamber 140 are within an appropriate gate valve 180 opening pressure range (i.e., the substrate handling chamber 120 and the reaction chamber 140 are within the predetermined pressure differential ΔP). Then, at Step S620, systems and methods according to some examples of this technology may generate an output to open the gate valve 180, unlock the gate valve 180, and/or otherwise enable the gate valve 180 to be opened (e.g., for computer controlled gate valves 180). Alternatively, systems and methods according to some examples of this technology may simply inform the operator that it is safe to open the gate valve 180 (e.g., to manually initiate the gate valve 180 opening event and/or the substrate transfer process).

Alternatively, the system and method of FIGS. 6A and 6B could be revised such that the substrate handling chamber 120's pressure control valve 130 is fixed at Step S606 and then pressure in the reaction chamber 140 could be increased at Step S614 or decreased at Step S618 using the reaction chamber 140's pressure control valve 150, if needed.

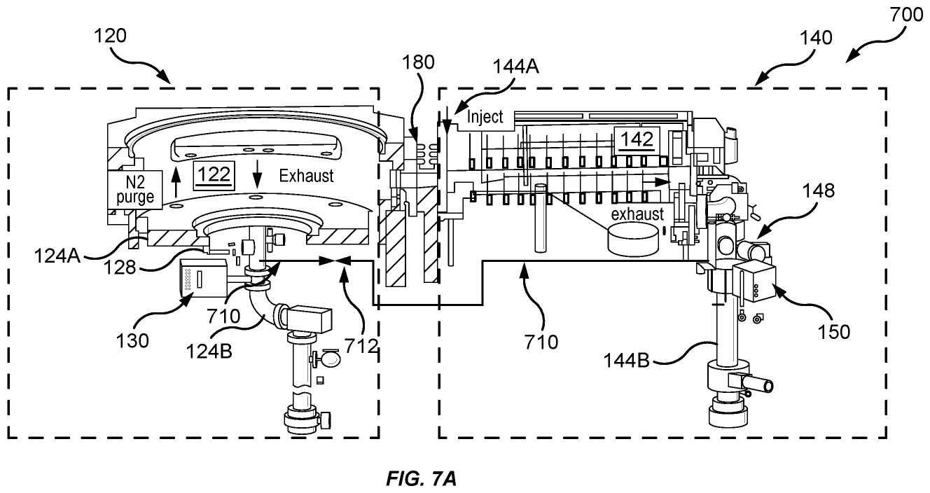

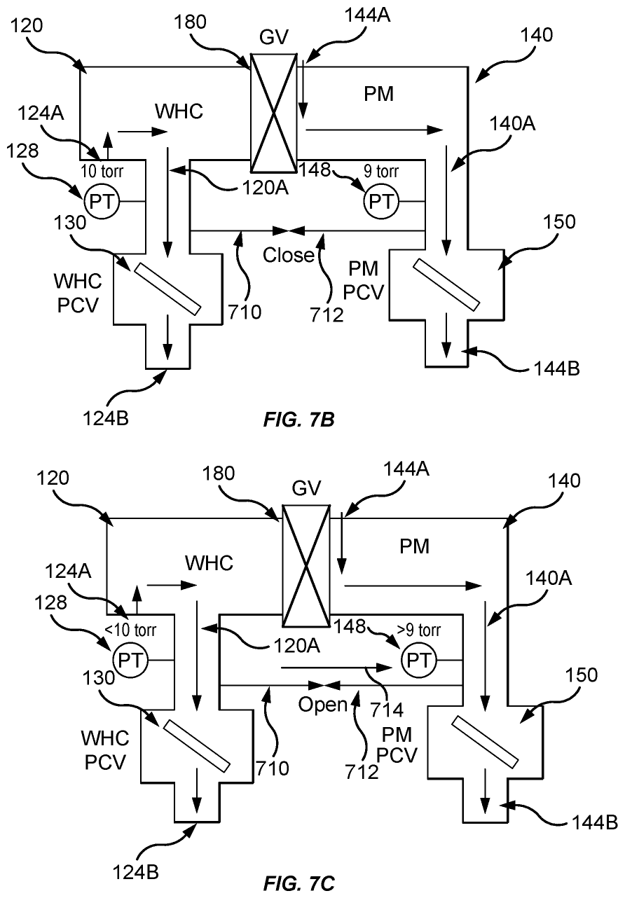

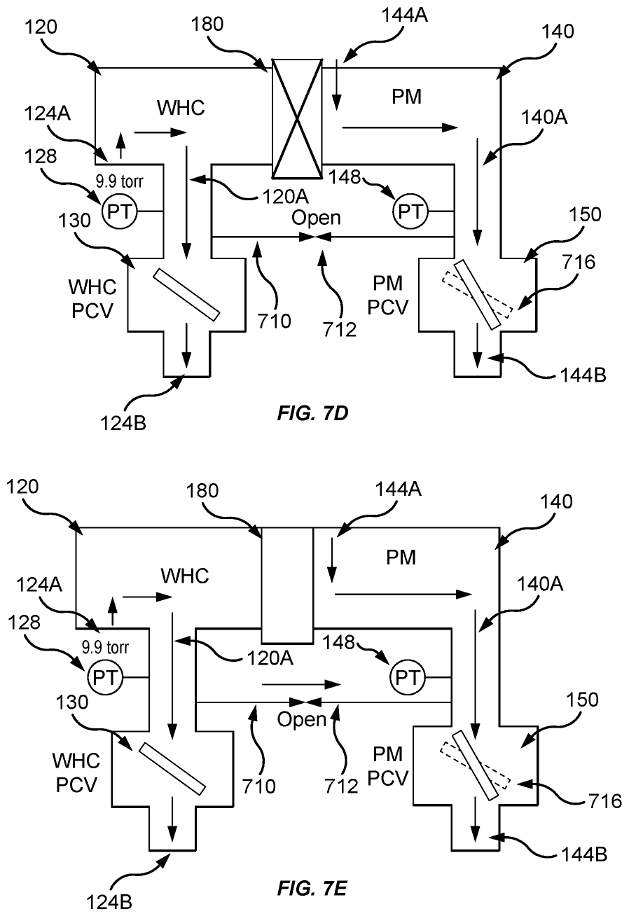

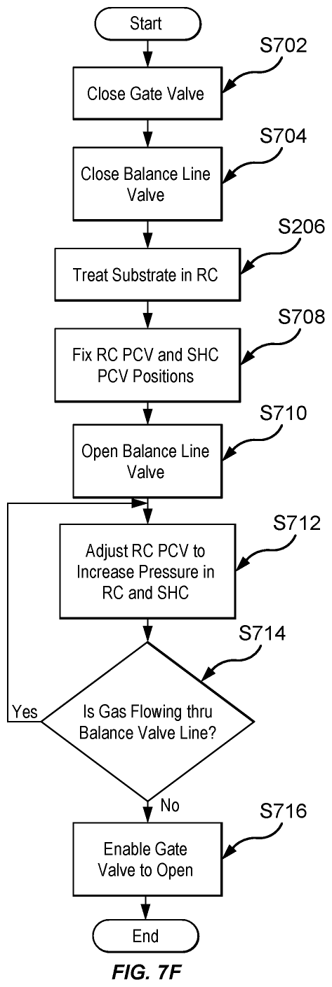

FIGS. 7A-7F illustrate another example system 700 and method for controlling pressure to assure a substrate handling chamber 120 and a reaction chamber 140 are within a predetermined gate valve 180 opening pressure range prior to initiating a gate valve 180 opening event. The system 700 of FIG. 7A may be similar to that of FIG. 1, e.g., with a substrate handling chamber 120 and a reaction chamber 140 connected by a gate valve 180 that can open and close, e.g., for a substrate 160 transfer event. Where the same reference numbers are used in FIGS. 7A-7F as used in other figures discussed above, the same or similar parts are being referenced, and much of the overlapping description may be omitted. Also, several parts in the system of FIGS. 7A-7E are not labeled in the figures, e.g., to avoid obscuring relevant information for the discussion below.

In one aspect, the system 700 of FIGS. 7A-7E differs from the substrate processing system 100 of FIG. 1 in that the system 700 of FIGS. 7A-7E includes a balance valve gas line 710 that connects the interior chambers 122, 142 of the substrate handling chamber 120 and the reaction chamber 140. The balance valve gas line 710 includes a valve 712 that may be changed between an open configuration and a closed configuration for reasons described in more detail below. While other options are possible, in this illustrated example, the balance valve gas line 710 extends between (and connects): (i) a location in the gas exhaust 124B line of the substrate handling chamber 120 and (ii) a location in the gas exhaust 144B line of the reaction chamber 140. In this manner, the balance valve gas line 710 connections are located downstream of the interior chambers 122, 142 of the substrate handling chamber 120 and the reaction chamber 140 (downstream with respect to the typical gas flow directions through the substrate handling chamber 120 and the reaction chamber 140). In at least some examples of this technology, the valve 712 may be equipped with a flow meter to measure gas flow through the valve 712 (or such a flow meter may be provided at another location along the balance valve gas line 710).

Operation of the system 700 in preparation for a gate valve 180 opening event now will be described in conjunction with FIGS. 7B-7F. Typical substrate 160 processing in the reaction chamber 140 (Step S706) takes place with the gate valve 180 in a closed configuration (Step S702) and with the valve 712 of the balance valve gas line 710 in a closed configuration (Step S704). During this time period, the gate valve 180 sealingly separates interior chambers 122 and 142 from one another, so these interior chambers 122, 142 may be at different pressures (e.g., any respective pressures needed for the activities taking place in the respective interior chambers 122, 142).

Eventually a time will come when a gate valve 180 opening event is needed (e.g., for a substrate transfer process). At that time, as noted above, the interior chambers 122, 142 may be at different pressures (e.g., each at their target set points, such as 10 torr for the substrate handling chamber 120 and 9 torr for the reaction chamber 140). See FIG. 7B. Thus, in some instances, these pressures may not be suitable for gate valve 180 opening operation (e.g., the pressure differential between the chambers may be outside a desired gate valve opening pressure range ΔP, such that increased gas exchange (and potential contamination) between the substrate handling chamber 120 and the reaction chamber 140 may occur if the gate valve 180 were opened).

Systems 700 and methods according to this aspect of the present technology take steps to assure the substrate handling chamber 120 and the reaction chamber 140 are at an appropriate pressure differential for a gate valve 180 opening event as described below. First the reaction chamber 140's pressure control valve 150 and the substrate handling chamber 120's pressure control valve 130 are set at fixed positions. See Step S708 in FIG. 7F. In some examples of systems and methods according to aspects of this technology, one or both pressure control valves 130, 150 may be computer controlled pressure control valves that are configured to be locked in place or disabled under computer control in order to assure their fixed positions and statuses. In other examples of this technology, either or both of the pressure control valves 130, 150 may be manually locked and/or operators may simply be instructed to maintain the pressure control valve(s) 130, 150 in their respective fixed positions during the steps that follow.

With the gate valve 180 closed and the pressure control valves 130, 150 at fixed positions, the valve 712 in the balance valve gas line 710 is opened. See gas flow arrow 714 in FIG. 7C and Step S710 in FIG. 7F. Because the pressure control valves 130, 150 are fixed, this valve 712 opening action causes gas to flow through the balance valve gas line 710 from the gas exhaust 124B line of the substrate handling chamber 120 to the gas exhaust line 144B of the reaction chamber 140 because pressure in the substrate handling chamber 120 was greater than pressure in the reaction chamber 140. This valve 712 opening action and resultant gas flow (see gas flow arrow 714) also causes a pressure drop in the substrate handling chamber 120 (e.g., to 9.9 torr) and a pressure increase in the reaction chamber 140. While some gas flows between the substrate handling chamber 120 and the reaction chamber 140 through balance valve gas line 710 in this example system and method, because the balance valve gas line 710 connects to the substrate handling chamber 120 and the reaction chamber 140 at their gas exhaust lines and downstream from their interior chambers 122, 142 in the typical gas flow direction, little to no contamination between interior chambers 122, 142 is expected from this valve 712 opening action. Rather, most or all exchanged gas via balance valve gas line 710 can be expected to be quickly removed via the respective gas exhausts 124B, 144B. The balance valve gas line 710 may be sized so that gas flow when valve 712 is opened is not too rapid.

Next, the reaction chamber 140's pressure control valve 150 is adjusted (e.g., manually or under automated computer control) to increase pressure in the reaction chamber 140 until it is substantially the same as pressure in the substrate handling chamber 120 (e.g., substantially the same as the substrate handling chamber 120's initial pressure set point, such as about 9.9 torr). See reference number 716 in FIG. 7D and Step S712 in FIG. 7F. The substrate handling chamber 120's pressure control valve 130 remains in its fixed position and gate valve 180 remains closed. At Step S714, this example system and method determines if the substrate handling chamber 120 and the reaction chamber 140 are at substantially the same pressure (due to adjustment of the pressure control valve 150). While other ways of making this determination are possible, in this specific example, the system and method determine if the substrate handling chambers 120 and the reaction chamber 140 are at substantially the same pressure by determining whether gas flows through the balance valve gas line 710 (and/or by determining the gas flow rate through the balance valve gas line 710). See Step S714. If the substrate handling chamber 120 and the reaction chamber 140 are not at substantially the same pressure, gas will continue to flow (or will flow at a faster rate) through the balance valve gas line 710 (answer “Yes” at Step S714) in an effort to equalize the pressures between the substrate handling chamber 120 and the reaction chamber 140. In that event, the method may return to Step S712 and further adjustment of the reaction chamber 140's pressure control valve 150 may occur while the substrate handling chamber 120's pressure control valve 130 remains at its fixed position.

On the other hand, if the substrate handling chamber 120 and the reaction chamber 140 are at substantially the same pressures, the gas flow rate through the balance valve gas line 710 will be at or substantially zero, e.g., below a predetermined flow rate (answer “no” at Step S714). In this event, the system and method may generate an output to open the gate valve 180, unlock the gate valve 180, and/or otherwise enable the gate valve 180 to be opened (e.g., for computer controlled gate valves 180). See FIG. 7E. Alternatively, systems and methods according to some examples of this technology may simply inform the operator that it is safe to open the gate valve 180 (e.g., to manually initiate the gate valve 180 opening event and/or the substrate transfer process).

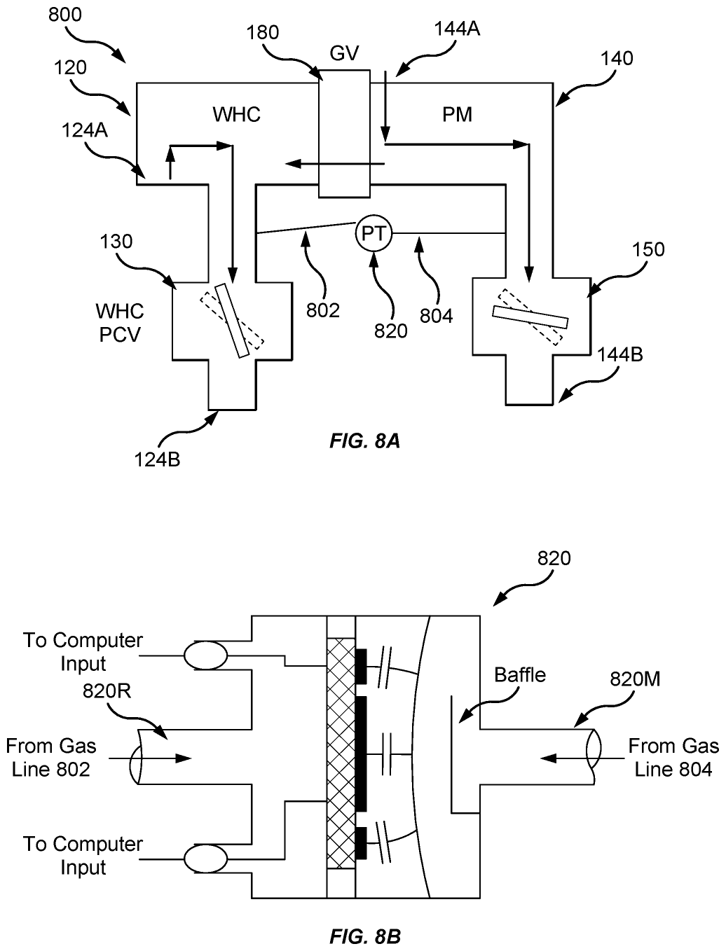

FIGS. 8A and 8B illustrate another example system 800 for determining whether gas pressures in a substrate handling chamber 120 and a reaction chamber 140 are within a predetermined gate valve 180 opening pressure range (e.g., whether the pressure differential between the substrate handling chamber 120 and the reaction chamber 140 is within a predetermined range ΔP). Where the same reference numbers are used in FIGS. 8A and 8B as used in other figures discussed above, the same or similar parts are being referenced, and much of the overlapping description may be omitted.

In the example system 800 of FIGS. 8A and 8B, rather than (or in addition to) providing each of the substrate handling chamber 120 and the reaction chamber 140 with its own separate pressure sensor (e.g., like pressure sensors 128 and 148 described above), a gas line from each of the substrate handling chamber 120 and the reaction chamber 140 connects to a differential pressure manometer 820. Differential pressure manometers of this type are known. In the illustrated example of FIGS. 8A and 8B, a gas line 802 (e.g., connected to the gas exhaust 124B line of the substrate handling chamber 120) connects with one port (e.g., the reference port 820R) of the differential pressure manometer 820. Also, a gas line 804 (e.g., connected to the gas exhaust 144B line of the reaction chamber 140) connects with another port (e.g., the measuring port 820M) of the differential pressure manometer 820. The differential pressure manometer 820 generates data indicating the pressure difference (if any) between the incoming pressure at ports 820R, 820M. This data may be used to control the pressure control valve 150 of reaction chamber 140 and/or the pressure control valve 130 of the substrate handling chamber 120 to change pressures, control pressures, and/or maintain pressures in the substrate handling chamber 120 and the reaction chamber 140 within desired pressure ranges (e.g., within a predetermined pressure differential range ΔP for a gate valve 180 opening event).

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. In a substrate processing system including a substrate handling chamber that transfers substrates into and out of a reaction chamber through a gate valve, a method of controlling pressure for a gate valve opening event comprises:
with the gate valve between the substrate handling chamber and the reaction chamber in a closed configuration thereby sealing the substrate handling chamber from the reaction chamber, fixing a reaction chamber pressure control valve at a first position, thereby holding the reaction chamber at a reaction chamber pressure;
measuring the reaction chamber pressure using a reaction chamber pressure sensor;
measuring a substrate handling chamber pressure in the substrate handling chamber using a substrate handling chamber pressure sensor; and
with the reaction chamber pressure control valve fixed at the first position, adjusting pressure in the substrate handling chamber using a substrate handling chamber pressure control valve to a pressure within a gate valve opening pressure range, wherein the gate valve opening pressure range is a pressure greater than or equal to the reaction chamber pressure but no more than the reaction chamber pressure plus a first predetermined amount.

2. The method according to claim 1, wherein said adjusting pressure in the substrate handling chamber includes comparing the reaction chamber pressure and the substrate handling chamber pressure, and
(a) if the reaction chamber pressure is greater than the substrate handling chamber pressure, adjusting the substrate handling chamber pressure control valve to increase pressure in the substrate handling chamber to a pressure within the gate valve opening pressure range, or
(b) if the substrate handling chamber pressure is greater than the reaction chamber pressure plus the first predetermined amount, adjusting the substrate handling chamber pressure control valve to decrease pressure in the substrate handling chamber to a pressure within the gate valve opening pressure range.

3. The method according to claim 1, wherein said adjusting pressure in the substrate handling chamber includes:
receiving input data representing the reaction chamber pressure;
receiving input data representing the substrate handling chamber pressure;
comparing the reaction chamber pressure and the substrate handling chamber pressure; and
(a) if the reaction chamber pressure is greater than the substrate handling chamber pressure, generating an output to control the substrate handling chamber pressure control valve to increase pressure in the substrate handling chamber to a pressure within the gate valve opening pressure range, or
(b) if the substrate handling chamber pressure is greater than the reaction chamber pressure plus the first predetermined amount, generating an output to control the substrate handling chamber pressure control valve to decrease pressure in the substrate handling chamber to a pressure within the gate valve opening pressure range.

4. The method according to claim 1, wherein prior to fixing the reaction chamber pressure control valve at the first position, the method further comprises:
with the gate valve open and after the substrate handling chamber pressure and the reaction chamber pressure stabilize with the gate valve open, calibrating the reaction chamber pressure sensor using output from the substrate handling chamber pressure sensor as a reference.

5. The method according to claim 4, wherein prior to said calibrating, the method comprises individually calibrating the substrate handling chamber pressure sensor and the reaction chamber pressure sensor.

6. The method according to claim 5, wherein said individually calibrating the substrate handling chamber pressure sensor and the reaction chamber pressure sensor occurs with the substrate handling chamber at a base calibration pressure for the substrate handling chamber and with the reaction chamber at a base calibration pressure for the reaction chamber.

7. The method according to claim 4, wherein after calibrating the reaction chamber pressure sensor using output from the substrate handling chamber pressure sensor as the reference, the method comprises:
closing the gate valve;
using pressure sensor information generated by the reaction chamber pressure sensor, adjusting the reaction chamber pressure to a target pressure set point using the reaction chamber pressure control valve;
using pressure sensor information generated by the substrate handling chamber pressure sensor, adjusting the substrate handling chamber pressure to the target pressure set point using the substrate handling chamber pressure control valve;
opening the gate valve; and
while opening the gate valve, monitoring outputs from the reaction chamber pressure sensor and the substrate handling chamber pressure sensor to determine if a pressure jump is sensed in at least one of the reaction chamber or the substrate handling chamber.

8. The method according to claim 1, wherein the first predetermined amount is 0.75 torr or less.

9. The method according to claim 1, further comprising:
enabling the gate valve to open when the substrate handling chamber pressure is within the gate valve opening pressure range.

10. A method of controlling pressure for a gate valve opening event in a substrate processing system that includes a substrate handling chamber that transfers substrates into and out of a reaction chamber through a gate valve, the method comprising:
with a reaction chamber pressure control valve for the reaction chamber fixed at a first position, thereby holding the reaction chamber at a reaction chamber pressure:
(a) receiving input indicating the reaction chamber pressure;
(b) receiving input indicating substrate handling chamber pressure;
(c) determining whether the reaction chamber pressure and the substrate handling chamber pressure are within a gate valve opening pressure range, wherein the reaction chamber pressure and the substrate handling chamber pressure are within the gate valve opening pressure range when the substrate handling chamber pressure is greater than or equal to the reaction chamber pressure but no more than the reaction chamber pressure plus a first predetermined amount; and
(d) controlling a substrate handling chamber pressure control valve to adjust the substrate handling chamber pressure until the reaction chamber pressure and the substrate handling chamber pressure are within the gate valve opening pressure range.

11. The method according to claim 10, further comprising at least one of:
enabling the gate valve to open when the reaction chamber pressure and the substrate handling chamber pressure are within the gate valve opening pressure range; and
disabling the gate valve from opening when the reaction chamber pressure and the substrate handling chamber pressure are outside the gate valve opening pressure range.

12. The method according to claim 10, wherein prior to fixing the reaction chamber pressure control valve at the first position, the method further comprises:
calibrating a reaction chamber pressure sensor using output from a substrate handling chamber pressure sensor as a reference.

13. The method according to claim 12, wherein prior to said calibrating, the method comprises individually calibrating the substrate handling chamber pressure sensor and the reaction chamber pressure sensor.

14. The method according to claim 13, wherein said individually calibrating the substrate handling chamber pressure sensor and the reaction chamber pressure sensor occurs with the substrate handling chamber at a base calibration pressure for the substrate handling chamber and with the reaction chamber at a base calibration pressure for the reaction chamber.

15. The method according to claim 12, wherein after calibrating the reaction chamber pressure sensor using output from the substrate handling chamber pressure sensor as the reference, the method comprises:
closing the gate valve;
using pressure sensor information generated by the reaction chamber pressure sensor, adjusting the reaction chamber pressure to a target pressure set point using the reaction chamber pressure control valve;
using pressure sensor information generated by the substrate handling chamber pressure sensor, adjusting the substrate handling chamber pressure to the target pressure set point using the substrate handling chamber pressure control valve;
opening the gate valve; and
while opening the gate valve, monitoring outputs from the reaction chamber pressure sensor and the substrate handling chamber pressure sensor to determine if a pressure jump is sensed in at least one of the reaction chamber or the substrate handling chamber.

16. The method according to claim 10, wherein the first predetermined amount is 0.75 torr or less.

17. A substrate processing system, comprising:
a reaction chamber;
a reaction chamber pressure sensor configured to measure reaction chamber pressure;
a reaction chamber pressure control valve;
a substrate handling chamber;
a substrate handling chamber pressure sensor configured to measure substrate handling chamber pressure;
a substrate handling chamber pressure control valve, wherein the substrate handling chamber pressure control valve is electronically controllable;
a gate valve between the reaction chamber and the substrate handling chamber, the gate valve switchable between an open configuration in which the reaction chamber and the substrate handling chamber are open to one another and a closed configuration in which the substrate handling chamber and the reaction chamber are sealed off from one another;
an input system configured to receive: (i) input data from the reaction chamber pressure sensor indicating the reaction chamber pressure, and (ii) input data from the substrate handling chamber pressure sensor indicating the substrate handling chamber pressure; and
a control system configured to send signals to adjust the substrate handling chamber pressure control valve in response to the input data from the reaction chamber pressure sensor and the input data from the substrate handling chamber pressure sensor and place the substrate handling chamber pressure within a gate valve opening pressure range, wherein the substrate handling chamber pressure is within the gate valve opening pressure range when the substrate handling chamber pressure is greater than or equal to the reaction chamber pressure but no more than the reaction chamber pressure plus a first predetermined amount.

18. The substrate processing system according to claim 17, wherein the control system further is configured to enable the gate valve to open when the substrate handling chamber pressure is within the gate valve opening pressure range.

19. The substrate processing system according to claim 18, wherein the control system further is configured to disable the gate valve from opening when the substrate handling chamber pressure is outside the gate valve opening pressure range.

20. The substrate processing system according to claim 17, wherein the control system further is configured to disable the gate valve from opening when the substrate handling chamber pressure is outside the gate valve opening pressure range.
